(19) United States
(12) Patent Application Publication
(10) Pub. No.: US 2012/0162941 A1
(43) Pub. Date: Jun. 28, 2012

(54) ELECTRONIC DEVICE WITH SWITCH

(75) Inventors: KUN-CHIH HSIEH, Tu-Cheng (TW); JIAN-QIANG ZHAO, Shenzhen City (CN); FAN-PENG ZENG, Shenzhen City (CN); JIAN ZENG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 13/163,739

(22) Filed: Jun. 20, 2011

(30) Foreign Application Priority Data
Dec. 22, 2010 (CN) 201010604383.5

(51) Int. Cl. H05K 7/00

(52) U.S. Cl. 361/752

(57) ABSTRACT

An electronic device includes a housing, a circuit board disposed in the housing, a female connector received in the housing, and a switch. The female connector is configured to receive and electrically connect a male connector, including a through hole, the through hole having a first opening exposed outside the housing for insertion of the male connector into the through hole therethrough and an opposing second opening located within the housing, the second opening aligned with the first opening. The switch is electrically connected to the circuit board adjacent to the second opening. The switch is able to be actuated by an elongated object passing through the second opening, and the electronic device is rebooted when the switch is actuated.

### BACKGROUND

1. Technical Field

The present disclosure relates to an electronic device with a switch.

2. Description of the Related Art

In certain conditions, for example, when an electronic device is in an abnormal mode, a user may need to actuate a predetermined reset switch to reboot the electronic device. However, the reset switch is disposed in the inner body of the electronic device, and an open end is defined in the body corresponding to the reset switch. It is incomplete and unaesthetic for the electronic device.

Therefore, there is room for improvement within the art.

### BRIEF DESCRIPTION OF THE DRAWINGS

The components in the drawings are not necessarily drawn to scale, the emphasis instead being placed upon clearly illustrating the principles of an electronic device with switch. Moreover, in the drawings, like reference numerals designate corresponding parts throughout the several views.

FIG. 1 is an isometric, partial view of an electronic device with switch in accordance with an exemplary embodiment.

FIG. 2 is similar to FIG. 1, but viewed from another aspect.

FIG. 3 is a cross-sectional side view of the electronic device in FIG. 1.

### DETAILED DESCRIPTION

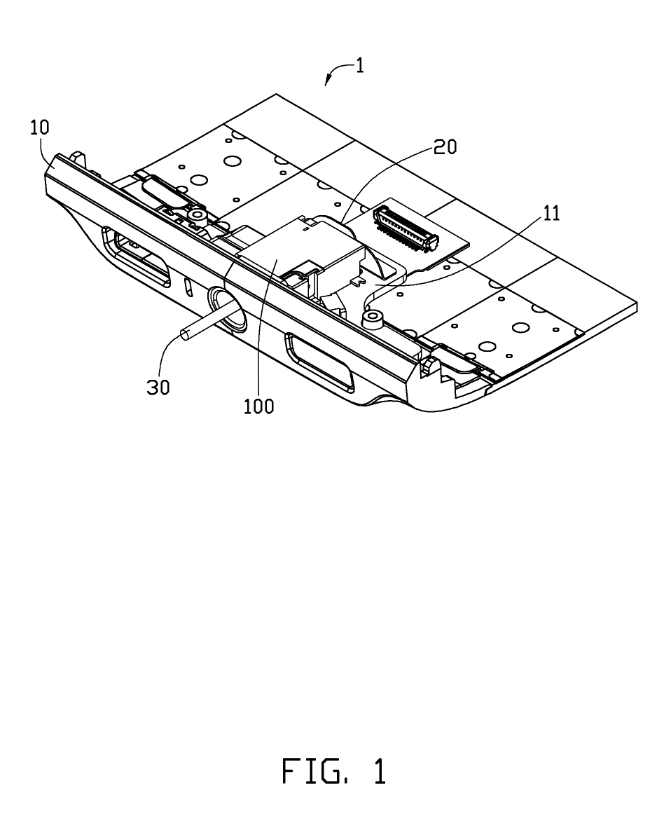

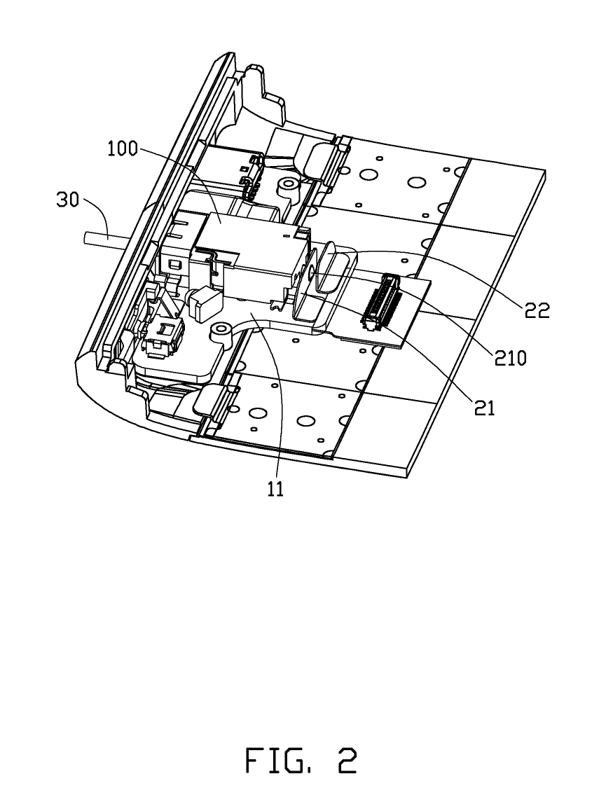

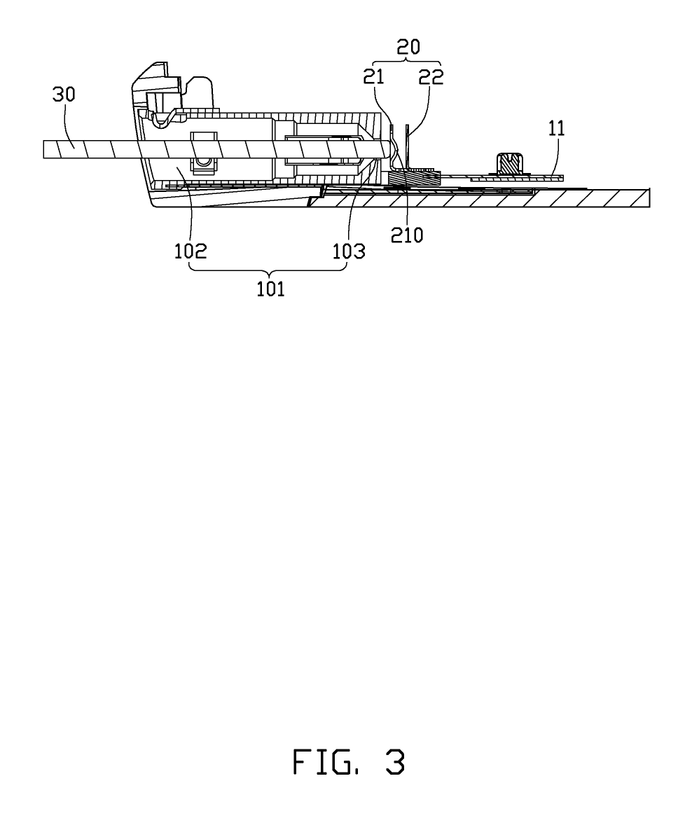

Referring to FIGS. 1, 2, and 3, an electronic device 1 includes a housing 10 and a switch 20 disposed in the housing 10. A female connector 100 is disposed in the housing 10, and is used for receiving and electrically connect a meal connector. In the embodiment, the female connector 100 is an audio jack female connector. In an alternative embodiment, the female connector is a video jack female connector. The female connector 100 includes a through hole 101, and the through hole 101 having a first opening 102 exposed outside the housing 10 for insertion of the male connector into the through hole therethrought and an opposing second opening 103 located with the housing 10, the second opening 103 is aligned with the first opening 102. A circuit board 11 is disposed in the housing 10.

The switch 20 is electrically connected to a reboot circuit (not shown) of the circuit board 11. The switch apparatus 20 includes a first spring tab 21 and a second spring tab 22 that are spaced from each other and mounted on the circuit board 11. The first spring tab 21 is adjacent to the second opening 103. The second spring tab 22 is arranged at an opposite side of the first spring tab 21 to the second opening 103. In the embodiment, the first spring tab 21 and the second spring tab 22 are parallel to each other. A contact portion 210 protrudes from the first spring tab 21 towards the second spring tab 22, the contact portion 210 is configured for touching the second spring tab 22 to actuate the switch 20 when the object presses the first spring tab 21.

When attempting to reboot the electronic device 1, a thin bar 30 can be inserted into the female connector 100 via the first open end 101. The end of the thin bar 30 will pass through the second open end 102 of the switch 100 to urge the first spring tab 21, which compresses the first spring tab 21. The contact portion 210 is pushed by the thin bar 30 to move and contact the second spring tab 22, thereby actuating the switch 20. The reboot circuit of the circuit board 11 reboots the electronic device 1 in response to the signal of the switch 20.

It is understood that the present disclosure may be embodied in other forms without departing from the spirit thereof. Thus, the present examples and embodiments are to be considered in all respects as illustrative and not restrictive, and the disclosure is not to be limited to the details given herein.

What is claimed is:

1. An electronic device comprising:
a housing;
a circuit board disposed in the housing;
a female connector received in the housing, and the female connector configured to receive and electrically connect a male connector, the female connector comprising a through hole, the through hole having a first opening exposed outside the housing for insertion of the male connector into the through hole therethrough and an opposing second opening located within the housing, the second opening aligned with the first opening; and
a switch electrically connected to the circuit board adjacent to the second opening, wherein the switch is configured to be actuated by an elongated object passing through the second opening , to reboot the electronic device.

2. The electronic device as recited in claim 1, wherein the switch comprising:
a first spring tab adjacent to the second opening, and mounted on the circuit board; and
a second spring tab arranged at an opposite side of the first spring tab to the second opening, the second spring tab being spaced from the first spring tab and mounted on the circuit board.

3. The electronic device as recited in claim 2, wherein the first spring tab and the second spring tab are parallel to each other.

4. The electronic device as recited in claim 2, wherein a contact portion protrudes from the first spring tab toward the second spring tab, the contact portion is configured for touching the second spring tab to actuate the switch when the object presses the first spring tab.

5. The electronic device as recited in claim 1, wherein the female connector is an audio jack female connector.

6. The electronic device as recited in claim 1, wherein the female connector is a video jack female connector.
